(19) United States
(12) Patent Application Publication
(10) Pub. No.: US 2023/0039285 A1
(43) Pub. Date: Feb. 9, 2023

(54) HYBRID METAL-OXIDE SEMICONDUCTOR FIELD-EFFECT TRANSISTOR WITH VARIABLE GATE IMPEDANCE AND IMPLEMENTATION METHOD THEREOF

(71) Applicant: Potens Semiconductor Corp., Zhubei City (TW)

(72) Inventors: Wen Nan HUANG, Zhubei City (TW); Ching Kuo CHEN, Zhubei City (TW); Shiu Hui LEE, Zhubei City (TW); Tung Ming LAI, Zhubei City (TW); Cho Lan PENG, Zhubei City (TW); Chuo Chien TSAO, Zhubei City (TW)

(21) Appl. No.: 17/533,700

(22) Filed: Nov. 23, 2021

(30) Foreign Application Priority Data
Aug. 3, 2021 (TW) 110128605

(51) Int. Cl. H03K 17/687

(52) U.S. Cl. CPC H03K 17/687

(57) ABSTRACT

A hybrid metal-oxide semiconductor field-effect transistor with variable gate impedance and an implementation method thereof, wherein the hybrid metal-oxide semiconductor field-effect transistor has the characteristic of changing the on-resistance according to different drive voltages. By use of a feedback loop and a variable gate drive voltage generator which can vary the generated gate drive voltage based on different loads, the present disclosure can still adjust the gate drive voltage under different load conditions without requiring a plurality of metal-oxide semiconductor field-effect transistors in series/parallel to achieve the lowest power loss.

### BACKGROUND OF INVENTION

### (1) Field of the Present Disclosure

The present disclosure relates to a metal-oxide semiconductor field-effect transistor, and more particularly to a metal-oxide semiconductor field-effect transistor which can change the gate drive voltage according to the load.

### (2) Brief Description of Related Art

The requirements for transistor switches are getting higher and higher. Volume reduction, frequency increase, and loss reduction have become important issues, because as the frequency increases, the switching state is constantly changed. Therefore, the accumulated switching loss cannot be underestimated. The substantial loss in the transistor are mainly the drive loss and conduction loss that occur in the gate. The proportion of the drive loss and the conduction loss is different under different load conditions. In other words, the conduction loss is extremely small under light load condition while the drive loss is more significant. Conversely, in the case of heavy load, the conduction loss accounts for a larger proportion than the drive loss. Therefore, if the transistor is intended to be widely employed in various load conditions, it is not possible to improve only one of the losses. it needs to optimize two kinds of losses according to different load conditions. For example,

Chinese Patent No. CN102931961A discloses a method and a device for controlling the power consumption of a metal oxide semiconductor unit, Firstly, by determining the load state of the transistor, and then further adjusting the drive power consumption according to the load state, and by controlling the drive voltage, the total power consumption in both the heavy load state and the light load state can be effectively reduced. The drive voltage can be achieved by connecting multiple metal-oxide semiconductor field-effect transistors in parallel and shielding each metal-oxide semiconductor field-effect transistor according to the situation. However, this method requires multiple sets of metal-oxide semiconductor field-effect transistors connected in parallel, thereby resulting in higher cost and volume. Accordingly, how to effectively adjust the drive power consumption according to the load condition while taking into account the manufacturing cost and the use space is a problem to be solved.

### SUMMARY OF INVENTION

It is a primary object of the present disclosure to provide a. hybrid metal-oxide semiconductor field-effect transistor with variable gate impedance that can adjust the on-resistance according to light and heavy loads.

According to the present disclosure, the hybrid metal-oxide semiconductor field-effect transistor with variable gate impedance includes a hybrid metal-oxide semiconductor field-effect transistor, a first feedback loop, and a variable gate drive voltage generator. When the hybrid metal-oxide semiconductor field-effect transistor is connected to a load, a first electrical signal can be transmitted to the variable gate drive voltage generator through the first feedback loop. The variable gate drive voltage generator generates a gate drive voltage based on the first electrical signal to drive the hybrid metal-oxide semiconductor field-effect transistor. The variable gate drive voltage generator generates a relatively high gate drive voltage under heavy load, and a relatively low gate drive voltage under light load, so that the hybrid metal-oxide semiconductor field-effect transistor can effectively reduce power consumption and achieve the best system efficiency under heavy load and light load respectively.

### BRIEF DESCRIPTION OF THE DRAWINGS

FIG. 1 is a circuit block diagram according to the present disclosure.

FIG. 2 is a table showing the relationship between on-resistance and gate drive voltage of the present disclosure.

FIG. 3 is an implementation view I of the present disclosure.

FIG. 4 is an implementation view II of the present disclosure.

FIG. 5 is an implementation view III of the present disclosure,

FIG. 6 is circuit block diagram of another embodiment of the present disclosure.

FIG. 7 is a table showing data of the output power and the power loss data of the present disclosure.

### DETAILED DESCRIPTION OF PREFERRED EMBODIMENTS

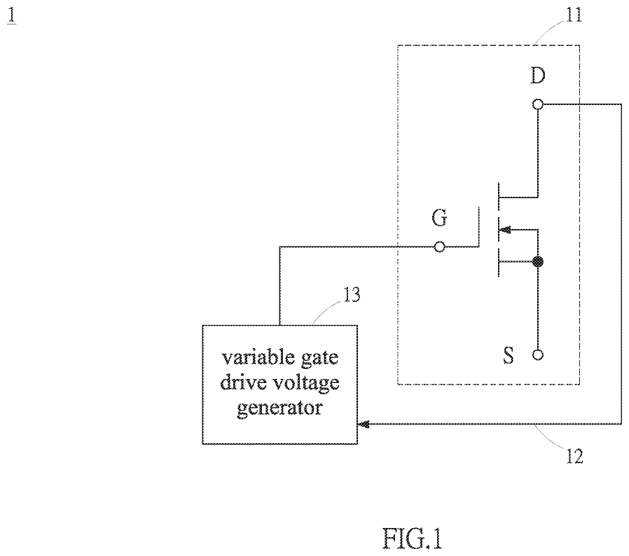

Referring to FIG. 1, a hybrid metal-oxide semiconductor field-effect transistor with variable gate impedance includes a. hybrid metal-oxide semiconductor field-effect transistor 11, a first feedback loop 12, and a variable gate drive voltage generator 13. The substantial components are detailed as follows:

The hybrid metal-oxide semiconductor field-effect transistor (Hybrid MOSFET) 11 includes a gate U, a source S, and a drain D. The hybrid metal-oxide semiconductor field-effect transistor 11 can, for example, achieve the effects of both super junction metal-oxide semiconductor field-effect transistor (SJ MOSFET, with high-speed switching and low on-resistance at low current) and insulated gate bipolar transistor (IGBT, with high voltage withstand and low on-resistance at high current). In this way, it performs well in both heavy load (with high current) and light load (with low current). In addition, the on-resistance (Rdson) of the hybrid metal-oxide semiconductor field-effect transistor 11 can be changed with a gate drive voltage (V_{GS}). For example, when the gate drive voltage is relatively larger, the on-resistance is smaller; on the contrary, when the gate drive voltage is relatively smaller, the on-resistance is larger.

One end of the first feedback loop 12 is electrically connected to the drain D of the hybrid metal-oxide semiconductor field-effect transistor 11 while the other end of the first feedback loop 12 is electrically connected to the variable gate drive voltage generator 13. The first feedback loop 12 can transmit a first electrical signal, such as the drain current I_{D}, generated by the hybrid metal-oxide semiconductor field-effect transistor 11 due to the load, to the variable gate drive voltage generator 13.

The variable gate drive voltage generator 13 is respectively electrically connected to the gate G of the hybrid metal-oxide semiconductor field-effect transistor 11 and the first feedback loop 12 for applying a gate drive voltage to the gate G of the hybrid metal-oxide semiconductor field-effect transistor 11 to control the conduction or disconnection of the hybrid metal-oxide semiconductor field-effect transistor 11. In addition, the variable gate drive voltage generator 13 uses a first electrical signal E1 generated by the load as a control signal and further generates a corresponding gate drive voltage based thereon. In this way, different gate driving voltages can be applied to the hybrid metal-oxide semiconductor field-effect transistor 11 under different load conditions.

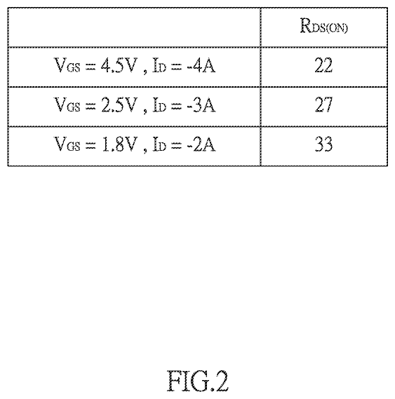

Referring to FIG. 2, when a first electrical signal E1 generated by the load is relatively high, the variable gate drive voltage generator 13 will generate a relatively high gate drive voltage. At that time, the hybrid metal-oxide semiconductor field-effect transistor 11 will have a low on-resistance (Rds(on)). As shown in FIG. 2, when the first electrical signal E1(I_{D})=−4 A, the gate drive voltage V_{GS}=4.5V, in this case, the on-resistance of 22 mΩ, is generated. When the first electrical signal E1 is low, the variable gate drive voltage generator 13 generates a lower gate drive voltage. Meanwhile, the hybrid metal-oxide semiconductor field-effect transistor 11 have a higher on-resistance (Rds(on)). As shown in FIG. 2, when the first electrical signal E1 (I_{D})=−2 A, the gate drive voltage V_{GS}=1.8V is generated. In this case, there will be an on-resistance of 33 mΩ.

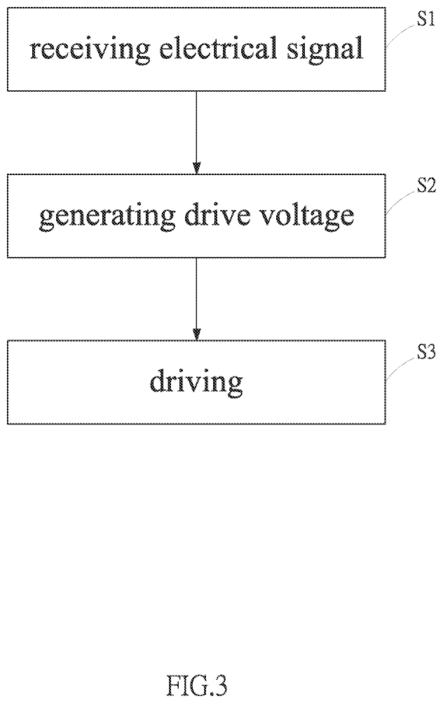

Referring to FIG. 3, the implementation method of the present disclosure is shown as follows:

Step S1 of receiving a first electrical signal, wherein, when the first electrical signal E1 generated by the load passes through the hybrid metal-oxide semiconductor field-effect transistor 11, the first feedback loop 12 transmits the first electrical signal E1 to the variable gate drive voltage generator 13. Meanwhile, the variable gate driving voltage generator 13 can determine the load size through the first electrical signal E1.

Step S2 of generating a drive voltage, wherein the variable gate driving voltage generator 13 uses a first electrical signal E1 as a control signal and performs modulation based on the control signal to generate a gate drive voltage V.

Step S3 of driving, wherein the variable gate drive voltage generator 13 transmits the gate drive voltage V to the hybrid metal-oxide semiconductor field-effect transistor 11, thereby driving it in an ON state. Different gate drive voltages V generate relatively different on-resistance, thereby effectively reducing the power loss according to different load conditions.

Optionally, the variable gate drive voltage generator 13 has at least one threshold, so that the gate drive voltage V can be adjusted according to different loads (ie, the first electrical signal E1) to achieve the minimum power loss. Regarding the influence of the gate drive voltage V generated under different load conditions on the power loss of the hybrid metal-oxide semiconductor field-effect transistor 11, the following two conditions are described for heavy load (with large current) and light load (with low current). However, it is hereby clarified according to the present disclosure that the gate drive voltage V is not limited to the two conditions.

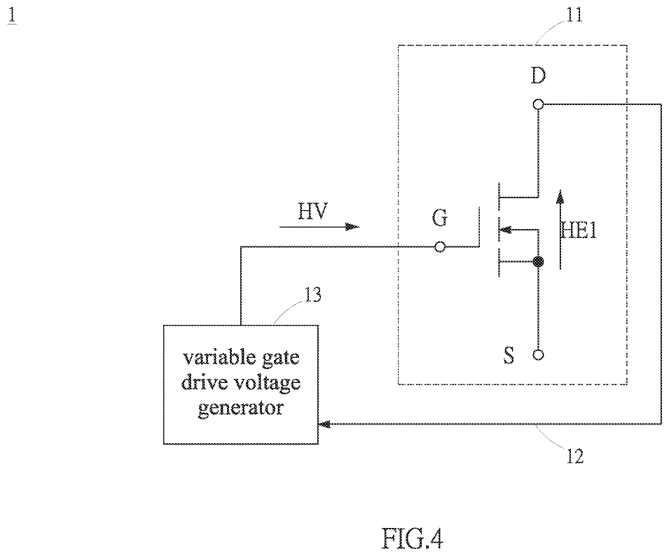

Referring to FIG. 4, when the load is a heavy load, a first electrical signal HE1 for heavy load, the variable gate drive voltage generator 13 generates a relatively high gate drive voltage HV to make the on-resistance (Rdson) of the hybrid metal-oxide semiconductor field-effect transistor 11 smaller. The conduction loss formed by the on-resistance (Rdson) under heavy load accounts for most of the overall loss of the system. Therefore, by increasing the gate drive voltage V to reduce the on-resistance (Rdson), the loss can be reduced under heavy load, thereby improving the efficiency.

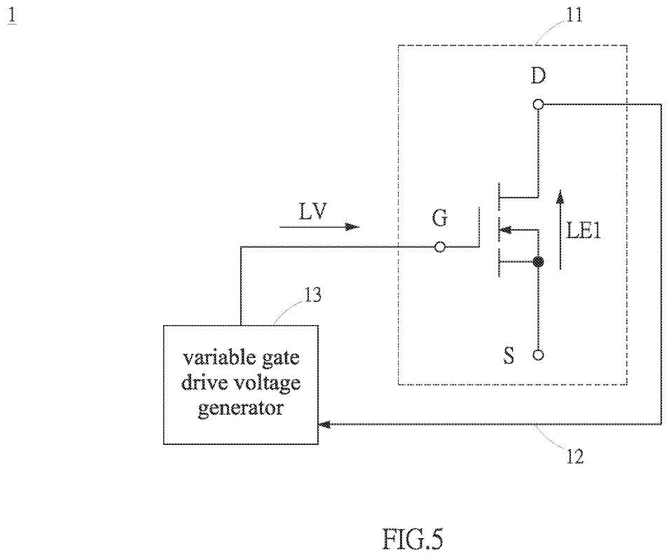

Referring to FIG. 5, when the load is a light load, a first electrical signal LE1 for light load is generated, the variable gate drive voltage generator 13 generates a relatively low gate drive voltage LV. The drive loss under heavy load accounts for most of the overall loss of the system. The smaller is the gate drive voltage V, the smaller is the drive loss. As a result, the loss can be reduced by lowering the gate drive voltage V under light-load or no-load standby conditions. In this way, the efficiency can be improved.

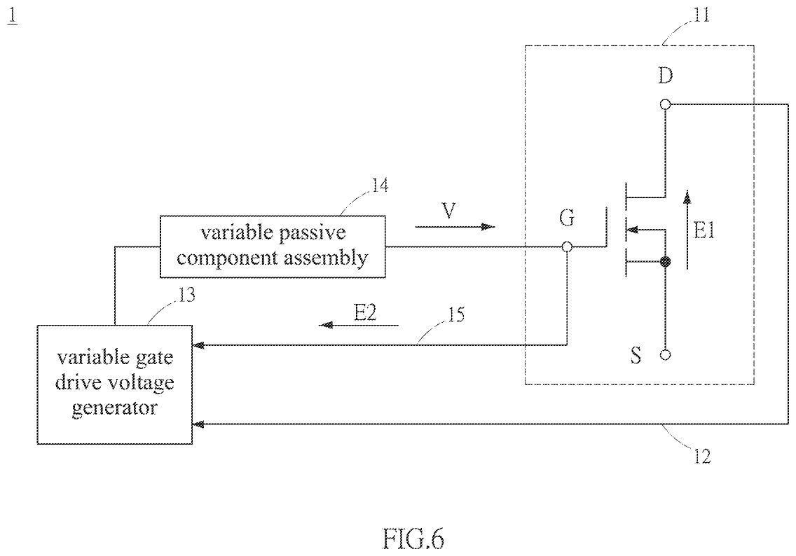

Referring to FIG. 6, the hybrid metal-oxide semiconductor field-effect transistor of the present disclosure includes a variable passive component assembly 14 and a second feedback loop 15. The variable passive component assembly 14 is electrically connected with the gate G of the hybrid metal-oxide semiconductor field-effect transistor 11 and the variable gate drive voltage generator 13. The second feedback loop 15 is electrically connected with the gate G of the hybrid metal-oxide semiconductor field-effect transistor 11 and the variable gate drive voltage generator 13. The variable passive component assembly 14 can be one of resistance, inductor, capacitance, or a combination thereof in series/parallel. The variable passive component assembly 14 can cooperate with the variable gate drive voltage generator 13 according to the first electrical signal E1 to control and compensate the gate drive voltage or to enhance the waveform of the gate drive voltage V. Moreover, the variable passive component assembly 14 can serve as a circuit sensing component to provide a second electrical signal E2, such as I_{G}, V_{GS}, I_{DS}, V_{DS}, which is transmitted to the variable gate drive voltage generator 13 through the second feedback loop 15. The variable gate drive voltage generator 13 can further use the second electrical signal E2 as a control signal to control the generated gate drive voltage. When the step S2 of generating a. drive voltage is performed, in addition to the aforementioned first electrical signal E1 as the control signal of the variable gate drive voltage generator 13, the variable passive component assembly 14 also serves as a circuit sensing element. The second electrical signal E2, such as: I_{G}, V_{GS}, I_{DS}, and V_{DS}, is provided and transmitted to the variable gate drive voltage generator 13 for use as another control signal to control the generated gate drive voltage V. In performing the step S3 of driving, the variable gate drive voltage generator 13 applies the gate drive voltage V to the hybrid metal-oxide semiconductor field-effect transistor 11. Furthermore, the gate drive voltage V can be compensated or the waveform can be enhanced by the variable passive component assembly 14.

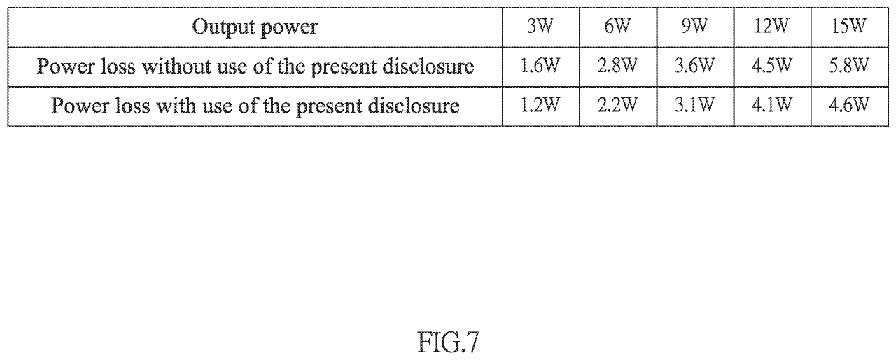

FIG. 7 shows the record of the power loss under each load condition. The first row of the table is the test condition of each load (output power) to test the power loss without the structure of the present disclosure (the second row of the table) and the power loss with the structure of the present disclosure (the third row of the table). It can be seen from the table that, with the hybrid metal-oxide semiconductor field-effect transistor of the present invention, under light load condition (for example, when the output power is 3 W), compared with the prior art, the power loss of the present disclosure is reduced from 1.6 W to 1.2 W. Under heavy load condition (for example, when the output power is 15 W), compared with the prior art, the power loss of the present disclosure is reduced from 5.8 W to 4.6 W. Therefore, the power loss under each load condition is significantly reduced. The present disclosure is indeed more efficient than the prior art in various load conditions.

According to the present disclosure, the first electrical signal and the second electrical signal generated by the variable passive component assembly serve as control signal to be sent to the variable gate drive voltage generator through the first feedback loop and the second feedback loop. The variable gate drive voltage generator can. generate different gate drive voltages according to the load conditions. Under heavy load, a relatively high gate drive voltage is generated for reducing the on-resistance, Under light load, a relatively low gate drive is generated for reducing the drive loss that accounts for most of the overall loss of the system. Accordingly, the present invention can effectively reduce power loss regardless of light load or heavy load, and. does not require a plurality of metal-oxide semiconductor field-effect transistors in series/parallel, which can effectively reduce cost and volume while also improving system efficiency.

### REFERENCE SIGN

1 hybrid metal-oxide semiconductor field-effect transistor with variable gate impedance
11 hybrid metal-oxide semiconductor field-effect transistor
12 first feedback loop
13 variable gate drive voltage generator
14 variable passive component assembly
15 second feedback loop
G gate
S source
D drain
E1 first electrical signal
E2 second electrical signal
HE1 first electrical signal for heavy load
LE2 first electrical signal for light load
HV gate drive voltage
LV gate drive voltage
gate drive voltage
S1 step of receiving a first electrical signal
S2 step of generating a drive voltage
S3 step of driving

1. A hybrid metal-oxide semiconductor field-effect transistor circuit with variable gate impedance for modulating a gate drive voltage according to a load so as to reduce power loss, comprising:
a hybrid metal-oxide semiconductor field-effect transistor having a gate, and an on-resistance changeable with the gate drive voltage, wherein the hybrid metal-oxide semiconductor field-effect transistor is composed of a super junction metal-oxide semiconductor field-effect transistor and an insulated gate bipolar transistor;
a first feedback loop electrically connected to the gate of the hybrid metal-oxide semiconductor field-effect transistor and a variable gate drive voltage generator, such that a first electrical signal generated by the hybrid metal-oxide semiconductor field-effect transistor due to the load is transmitted to the variable gate drive voltage generator;
wherein the variable gate drive voltage generator uses the first electrical signal as a control signal with which the gate drive voltage is generated.

2. The hybrid metal-oxide semiconductor field-effect transistor circuit with variable gate impedance as claimed in claim 1, wherein a variable passive component assembly is electrically connected to the gate of the hybrid metal-oxide semiconductor field-effect transistor and the variable gate drive voltage generator, respectively, and wherein the variable passive component assembly cooperates with the variable gate drive voltage generator based on the first electrical signal to control and compensate the gate drive voltage or to enhance the waveform of the gate drive voltage.

3. The hybrid metal-oxide semiconductor field-effect transistor circuit with variable gate impedance as claimed in claim 2, wherein a second feedback loop is electrically connected to the gate of the hybrid metal-oxide semiconductor field-effect transistor and the variable gate drive voltage generator, respectively, such that a second electrical signal generated by the variable passive component assembly is transmitted to the variable gate drive voltage generator through the second feedback loop, and wherein the gate drive voltage generated by the variable gate drive voltage generator is controlled by the second electrical signal.

4. (canceled)

5. The hybrid metal-oxide semiconductor field-effect transistor circuit with variable gate impedance as claimed in claim 3, wherein the first electrical signal and the second electrical signal are one of IG, VGS, IDS, VDS, or a combination thereof.

6. An implementation method of using a hybrid metal-oxide semiconductor field-effect transistor circuit with variable gate impedance, wherein a gate drive voltage is modulated according to a load for reducing power loss, comprising the following steps:
receiving a first electrical signal, wherein the hybrid metal-oxide semiconductor field-effect transistor generates a first electrical signal due to the load, and wherein the first electrical signal is transmitted through a first feedback loop to a variable gate drive voltage generator, wherein the hybrid metal-oxide semiconductor field-effect transistor is composed of a super junction metal-oxide semiconductor field-effect transistor and an insulated gate bipolar transistor;
generating the gate drive voltage, wherein the variable gate drive voltage generator uses the first electrical signal as a control signal for modulating a drive voltage and then generates the gate drive voltage; and
driving the hybrid metal-oxide semiconductor field-effect transistor, wherein the gate drive voltage is transmitted by the variable gate drive voltage generator to the hybrid metal-oxide semiconductor field-effect transistor for driving the hybrid metal-oxide semiconductor field-effect transistor.

7. The implementation method as claimed in claim 6, wherein the step of generating the drive voltage includes a sub-step of sensing a current through a variable passive component assembly for generating a second electrical signal, and wherein the second electrical signal is transmitted by a second feedback loop to the variable gate drive voltage generator so as to modulate the gate drive voltage generated by the variable gate drive voltage generator.

8. The implementation method as claimed in claim 7, wherein the step of driving the hybrid metal-oxide semiconductor field-effect transistor includes a sub-step of compensating the gate drive voltage or enhancing a waveform thereof through the variable passive component assembly.

9. (canceled)

10. The implementation method as claimed in claim 7, wherein the first electrical signal and the second electrical signal are one of IG, VGS, IDS, VDS, or a combination thereof.
